(19) United States
(12) Patent Application Publication
(10) Pub. No.: US 2018/0263080 A1
(43) Pub. Date: Sep. 13, 2018

(54) OVERHEAT PROTECTION CIRCUIT

(71) Applicant: HON HAI PRECISION INDUSTRY CO., LTD., New Taipei (TW)

(72) Inventor: CHIA-TING CHANG, New Taipei (TW)

(73) Assignee: HON HAI PRECISION INDUSTRY CO., LTD., New Taipei (TW)

(21) Appl. No.: 15/479,246

(22) Filed: Apr. 4, 2017

(30) Foreign Application Priority Data
Mar. 13, 2017 (CN) 201710145872.0

(51) Int. Cl. H05B 1/02; H05K 7/20

(52) U.S. Cl. CPC H05B 1/0288; H05B 2203/035; H05K 7/20136

(57) ABSTRACT

An overheat protection circuit able to detect and control the temperature of a electric heater includes a detecting unit, a controlling unit, and a electronic switch. The electronic switch is coupled between the electric heater and a first power supply and cuts off the power supply when overheating is electronically detected.

### FIELD

The subject matter herein generally relates to protection circuit preventing overheating.

### BACKGROUND

Traditional electric heaters need to be protected against overheating. Using a thermistor for temperature detection requires knowing or finding a temperature detection point for temperature detection.

### BRIEF DESCRIPTION OF THE DRAWINGS

Implementations of the present technology will now be described, by way of example only, with reference to the attached figures.

FIG. 1 is a schematic diagram of an exemplary embodiment of an overheat protection circuit.

FIG. 2 is a circuit diagram of a first exemplary embodiment of the overheat protection circuit.

FIG. 3 is a circuit diagram of a second exemplary embodiment of the overheat protection circuit.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

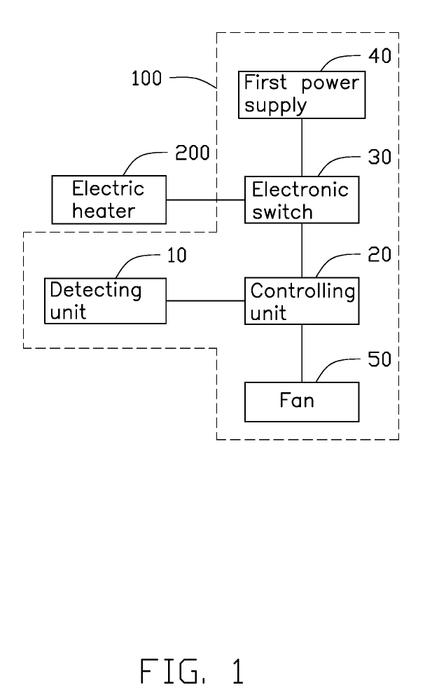

FIG. 1 illustrates an overheat protection circuit 100 of an exemplary embodiment. The overheat protection circuit 100 is configured to detect and control the temperature of an electric heater 200.

The overheat protection circuit 100 comprises a detecting unit 10, a controlling unit 20, an electronic switch 30, a first power supply 40, and a fan 50. The first power supply 40 is coupled to the electric heater 200 through the electronic switch 30, to output a working voltage to the electric heater 200. The electric heater 200 receives the working voltage from the first power supply 40 to perform heating function.

The detecting unit 10 detects the temperature of the electric heater 200, and outputs a temperature detection signal according to the temperature of the electric heater 200.

The controlling unit 20 receives the temperature detection signal from the detecting unit 10, and outputs a switch signal according to the temperature detection signal. The controlling unit 20 controls the fan 50 to dissipate heat from the system according to the received temperature detection signal.

The electronic switch 30 receives switch signal from the controlling unit 20, and controls whether the first power supply 40 supplies power for the electric heater 200.

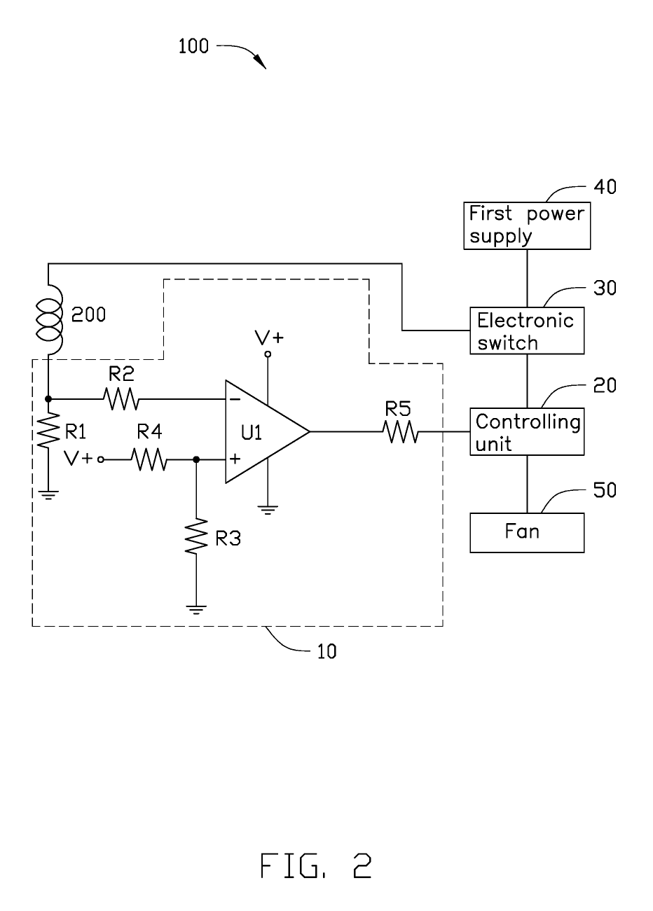

FIG. 2 illustrates a circuit diagram of a first exemplary embodiment of the overheat protection circuit 100. The detecting unit 10 comprises a comparator U1 and five resistors, R1-R5.

A first terminal of the electric heater 200 is grounded through the resistor R1, and a second terminal of the electric heater 200 is electrically coupled to the electronic switch 30. An inverting input terminal of the comparator U1 is electrically coupled to a node between the electric heater 200 and the resistor R1 through the resistor R2. The non-inverting input terminal of the comparator U1 is grounded through the resistor R3. The non-inverting input terminal of the comparator U1 is also electrically coupled to a second power supply V+ through the resistor R4. A power supply terminal of the comparator U1 is electrically coupled to the second power supply V+. A ground terminal of the comparator U1 is grounded. An output terminal of the comparator U1 is electrically coupled to controlling unit 20 through the resistor R5. The controlling unit 20 is coupled between the electronic switch 30 and the fan 50.

When the electric heater 200 receives the working voltage and starts to get hot, the electric resistance of the electric heater 200 is increased so that the current flowing through the electric heater 200 is reduced. The voltage detected and received by the inverting input terminal of the comparator U1 is reduced. When the detected voltage received by the inverting input terminal of the comparator U1 is smaller than the reference voltage received by the non-inverting input terminal of the comparator U1, the output terminal of the comparator U1 outputs a temperature detection signal at high-level logic to the controlling unit 20. The controlling unit 20 outputs a switch signal to turn off the electronic switch 30. The power supply unit 40 ceases to provide the working voltage to the electric heater 200. At the same time, the controlling unit 20 controls the fan 50 to dissipate heat from the system.

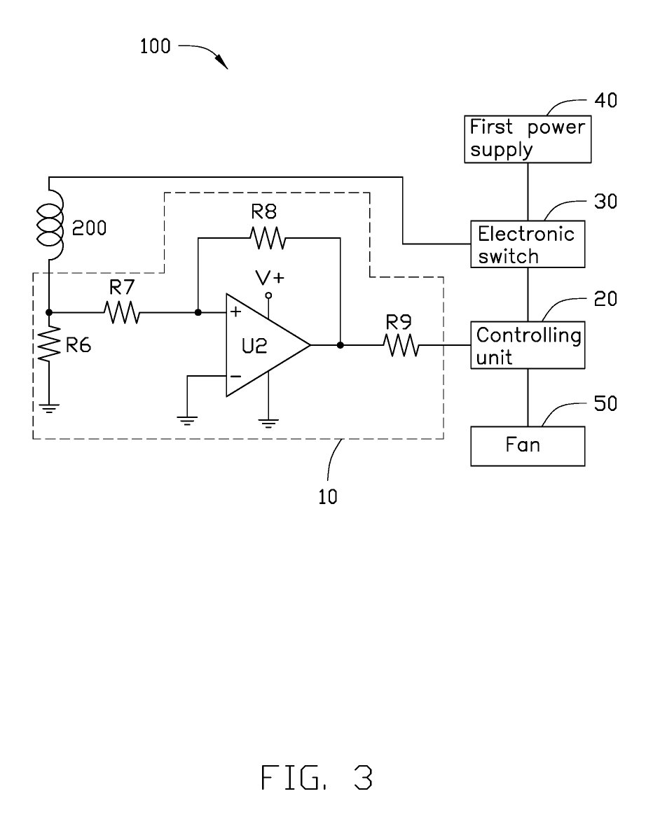

FIG. 3 illustrates a circuit diagram of a second exemplary embodiment of the overheat protection circuit 100. The detecting unit 10 comprises an amplifier U2 and four resistors R6-R9.

The first terminal of the electric heater 200 is grounded through the resistor R6, and the second terminal of the electric heater 200 is electrically coupled to the electronic switch 30. An inverting input terminal of the amplifier U2 is electrically coupled to a node between the electric heater 200 and the resistor R6 through the resistor R7. The inverting input terminal of the amplifier U2 is electrically coupled to an output terminal of the amplifier U2 through the resistor R8. The non-inverting input terminal of the amplifier U2 is grounded. The power supply terminal of the amplifier U2 is electrically coupled to the second power supply V+. A ground terminal of the amplifier U2 is grounded. The output terminal of the amplifier U2 is electrically coupled to controlling unit 20 through the resistor R9. The controlling unit 20 is coupled between the electronic switch 30 and the fan 50.

When the electric heater 200 receives the working voltage and starts to get hot, the electric resistance of the electric heater 200 is increased so that the current flowing through the electric heater 200 is reduced, and the detection voltage received by the non-inverting terminal of the comparator U1 is reduced. The amplifier U2 amplifies the detected voltage and outputs a different level of temperature detection signal to the controlling unit 20. The controlling unit 20 outputs the switch signal to the electronic switch 30 accordingly and the electronic switch 30 is turned off. The power supply unit 40 ceases to provide the working voltage to the electric heater 200. At the same time, the controlling unit 20 controls the fan 50 to change speed to dissipate heat from the system. The change in speed depends upon the different levels of temperature detection signals.

In this way, it is possible to stop supplying electric power to the electric heater 200 when the electric heater is working abnormally, to prevent the electric heater from overheating.

The exemplary embodiments shown and described above are only examples. Many details are often found in the art such as the other features of overheat protection circuit. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. An overheat protection circuit comprising:
a detecting unit configured for detecting the temperature of an electric heater, and outputting a temperature detection signal;
a controlling unit configured for receiving the temperature detection signal from the detecting unit, and outputting a switch signal;
a first power supply configured for providing a working voltage to the electric heater; and
an electronic switch coupled between the electric heater and the first power supply;
wherein the electronic switch receives the switch signal from the controlling unit, and controls whether the first power supply provides the working voltage for the electric heater.

2. The overheat protection circuit of claim 1, wherein the temperature detection circuit further comprises a fan, and the controlling unit is coupled between the electronic switch and the fan; when the controlling unit receives the temperature detection signal from the detecting unit, the controlling unit controls the fan to dissipate heat from the system.

3. The overheat protection circuit of claim 1, wherein the detecting unit comprises a comparator and a first, a second, a third, and a fourth resistors; a first terminal of the electric heater is grounded through the first resistor, a second terminal of the electric heater is electrically coupled to the electronic switch; an inverting input terminal of the comparator is electrically coupled to a node between the electric heater and the first resistor through the second resistor, a non-inverting input terminal of the comparator is grounded through the third resistor, a power supply terminal of the comparator is electrically coupled to the second power supply, a ground terminal of the comparator is grounded, and an output terminal of the comparator is electrically coupled to controlling unit through the fourth resistor.

4. The overheat protection circuit of claim 3, wherein the detecting unit further comprises a fifth resistor, and the non-inverting input terminal of the comparator is also electrically coupled to a second power supply through the fifth resistor.

5. The overheat protection circuit of claim 1, wherein the detecting unit comprises an amplifier and a first, a second, and a third resistors; a first terminal of the electric heater is grounded through the first resistor, and a second terminal of the electric heater is electrically coupled to the electronic switch; an inverting input terminal of the amplifier is electrically coupled to a node between the electric heater and the first resistor through the second resistor, and a non-inverting input terminal of the amplifier is grounded; a power supply terminal of the amplifier is electrically coupled to a second power supply, a ground terminal of the amplifier is grounded, and an output terminal of the amplifier is electrically coupled to controlling unit through the third resistor.

6. The overheat protection circuit of claim 5, wherein the detecting unit further comprises a fourth resistor, and the inverting input terminal of the amplifier is coupled to the output terminal of the amplifier through the fourth resistor.

7. An overheat protection circuit comprising:
a fan;
a detecting unit configured for detecting the temperature of an electric heater, and outputting a temperature detection signal;
a controlling unit configured for receiving the temperature detection signal from the detecting unit, and outputting a switch signal;
a first power supply configured for providing a working voltage to the electric heater; and
an electronic switch coupled between the electric heater and the first power supply;
wherein the electronic switch receives the switch signal from the controlling unit, and controls whether the first power supply provides the working voltage for the electric heater; and
wherein the controlling unit is coupled between the electronic switch and the fan, when the controlling unit receives the temperature detection signal from the detecting unit, the controlling unit controls the fan to dissipate heat from the system.

8. The overheat protection circuit of claim 7, wherein the detecting unit comprises a comparator and a first, a second, a third, and a fourth resistors; a first terminal of the electric heater is grounded through the first resistor, a second terminal of the electric heater is electrically coupled to the electronic switch; an inverting input terminal of the comparator is electrically coupled to a node between the electric heater and the first resistor through the second resistor, a non-inverting input terminal of the comparator is grounded through the third resistor, a power supply terminal of the comparator is electrically coupled to the second power supply, a ground terminal of the comparator is grounded, and an output terminal of the comparator is electrically coupled to controlling unit through the fourth resistor.

9. The overheat protection circuit of claim 8, wherein the detecting unit further comprises a fifth resistor, and the non-inverting input terminal of the comparator is also electrically coupled to a second power supply through the fifth resistor.

10. The overheat protection circuit of claim 7, wherein the detecting unit comprises an amplifier and a first, a second, and a third resistors; a first terminal of the electric heater is grounded through the first resistor, and a second terminal of the electric heater is electrically coupled to the electronic switch; an inverting input terminal of the amplifier is electrically coupled to a node between the electric heater and the first resistor through the second resistor, and a non-inverting input terminal of the amplifier is grounded; a power supply terminal of the amplifier is electrically coupled to a second power supply, a ground terminal of the amplifier is grounded, and an output terminal of the amplifier is electrically coupled to controlling unit through the third resistor.

11. The overheat protection circuit of claim 10, wherein the detecting unit further comprises a fourth resistor, and the inverting input terminal of the amplifier is electrically coupled to the output terminal of the amplifier through the fourth resistor.
